(19) United States
(12) Patent Application Publication
(10) Pub. No.: US 2010/0327951 A1
(43) Pub. Date: Dec. 30, 2010

(54) Semiconductor integrated circuit

(75) Inventor: Atsuhisa Fukuoka, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kanagawa (JP)

(21) Appl. No.: 12/662,712

(22) Filed: Apr. 29, 2010

(30) Foreign Application Priority Data
Jun. 30, 2009 (JP) 2009-154732

(51) Int. Cl. H03K 17/14

(52) U.S. Cl. 327/512

(57) ABSTRACT

A semiconductor integrated circuit includes a first circuit, a second circuit and a control circuit. The first circuit is configured by a first MOS transistor, and a threshold voltage of the first MOS transistor is a first threshold voltage. The second circuit has same logic as the first circuit, and is configured by a second MOS transistor. A threshold voltage of the second MOS transistor is a second threshold voltage, and the second threshold voltage is lower than the first threshold voltage. The control circuit makes one of the first circuit and the second circuit operate depending on a temperature of a chip. The first circuit and the second circuit are installed in a chip.

### INCORPORATION BY REFERENCE

This application is based upon and claims the benefit of priority from Japanese patent application No. 2009-154732, filed on Jun. 30, 2009, the disclosure of which is incorporated herein in its entirety by reference.

### BACKGROUND

1. Field of the Invention

The present invention relates to a semiconductor integrated circuit, and particularly to a semiconductor integrated circuit which has expanded operation temperature range and reduces leak current.

2. Description of Related Art

Recently, semiconductor integrated circuits are required to operate in a wide temperature range along with expanding operation temperature range in consequence of increasing opportunities that devices mounting semiconductor integrated circuits are used outdoors. A power supply voltage tends to decrease because of progress of process techniques used for semiconductor integrated circuits. For example, the power supply voltage of a semiconductor integrated circuit configured by CMOS (Complementary Metal Oxide Semiconductor) is 1.5V±0.15V with 0.15 μm process, and 1.0V±0.1V or 1.2V±0.12V with 90 nm process, which means the power supply voltage is decreased as the process is developed.

However, with decreasing the power supply voltage, an operation margin between a threshold voltage of transistors used in a semiconductor integrated circuit and a power supply voltage is decreased, therefore it becomes difficult to ensure the operation of the transistors with wide temperature range.

Further, with evolving the process, the semiconductor integrated circuit increases a gate leak current as a gate oxide film becomes thinner. A device mounting a recent semiconductor integrated circuit is required to significantly reduce consumption power to deal with global environmental issues, therefore low power is required not only in circuits during an operation but also in transistors during a standby state. That is, transistors are required to reduce their leak electrical power which is consumed in the standby state.

Generally, a leak electrical power of transistors used in a semiconductor integrated circuit is low when the threshold voltage is high, and high when the threshold voltage is low. Further a leak electrical power of transistors in high temperature operation tends to be higher than that in low temperature operation even in the same transistor.

To decrease leak electrical power at high temperature, a substrate bias control technique is widely used. The substrate bias control technique is a technique which controls a substrate voltage of the semiconductor integrated circuit and achieves an effect that threshold voltage can be increased by increasing the substrate voltage during high temperature.

However, this substrate bias control technique cannot be employed easily because its function implementation is complicated. As mentioned above, semiconductor integrated circuits in recent years have been required to have wide operation temperature range and low leak electrical power during high temperature. However, it is difficult to achieve these two requirements.

Japanese Patent No. 3838655 (Sakiyama et al.), Japanese Unexamined Patent Application Publication Nos. 2001-339045 (Ono et al.) and 5-29583 (Sato et al.) disclose a method for reducing a leak current during high temperature by controlling a substrate voltage of a semiconductor integrated circuit. FIG. 4 is a view describing a technique of Sakiyama et al. As shown in FIG. 4, Sakiyama et al. controls a substrate voltage by operation voltage value of a semiconductor chip and reduces a leak current by controlling sub threshold current flowing in the semiconductor substrate.

FIG. 5 is a view describing a technique of Ono et al. As shown in FIG. 5, Ono et al. detects applied state itself of a substrate bias voltage of a semiconductor chip and reduces a sub threshold current by setting the substrate bias to appropriate substrate voltage.

FIG. 6 is a view describing a technique of Sato et al. As shown in FIG. 6, Sato et al. detects a temperature of a semiconductor chip and reduces sub threshold current of the semiconductor chip during high temperature by controlling sub threshold current of the semiconductor chip based on temperature information. These techniques disclosed in FIGS. 4 to 6 particularly aim to reduce sub threshold current flowing in a substrate of the semiconductor chip.

A conventional semiconductor chip increases a leak current of a transistor because threshold of a transistor used in the semiconductor chip is decreased when temperature is high. On the other hand, techniques of Sakiyama et al., Ono et al., and Sato et al., increase the threshold voltage forcibly by increasing the substrate voltage of the semiconductor chip and decrease a leak current of a semiconductor chip.

The control of a substrate voltage of a semiconductor chip needs a control circuit which controls the substrate voltage in the semiconductor chip and the method for controlling is not easy. Therefore it is not easy to control the substrate bias.

Further, current semiconductor chip has many kinds of transistors so as to use different transistors having different threshold voltages for different operation speeds. Generally, a semiconductor chip uses a transistor whose threshold voltage (VT) is high, a transistor whose threshold voltage is middle, and a transistor whose threshold voltage is low.

Here, a transistor whose VT is high (high VT transistor) has low leak current, and a transistor whose VT is low (low VT transistor) has high leak current. Further, these transistors increase leak current during high temperature operation, and leak current of a low VT transistor tends to be larger than that of a high VT transistor.

When the above-mentioned semiconductor integrated circuit with transistor operates in low temperature, a threshold voltage of a transistor is increased as the temperature is low. Therefore threshold voltage of a high VT transistor is increased further compared with normal or high temperature. To operate a high VT transistor, it is required that a power supply voltage which is supplied from outside to a semiconductor integrated circuit is increased further comprised with normal or high temperature.

Note that, a threshold voltage of a low VT transistor is originally low, therefore even when temperature is low and the threshold voltage is increased, it is not necessary for a low VT transistor to increase a power supply voltage as high as a high VT transistor.

### SUMMARY

As discussed previously, a semiconductor chip which is configured by high VT transistors in consideration of low leak electrical power at the high temperature has lower leak current than a chip configured by low VT transistors. However, it is required to increase a power supply voltage supplied to the semiconductor chip to operate this semiconductor chip at low temperature.

Further, large amount of leak current flows in a semiconductor chip which is configured by low VT transistors in consideration of operation at the low temperature than high VT transistors. Therefore, a specific design is required to reduce leak current by using a substrate bias technique which has an effect to increase a threshold voltage to reduce leak current at high temperature.

Thus, it is desired to realize a semiconductor integrated circuit which can reduce a leak current and realizes operation in a wide temperature range.

According to an embodiment of the present invention, there is provided a semiconductor integrated circuit including a first circuit, a second circuit and a control circuit. The first circuit is configured by a first MOS transistor, and a threshold voltage of the first MOS transistor is a first threshold voltage. The second circuit has same logic as the first circuit, and is configured by a second MOS transistor. A threshold voltage of the second MOS transistor is a second threshold voltage, and the second threshold voltage is lower than the first threshold voltage. The control circuit makes one of the first circuit and the second circuit operate depending on a temperature of a chip. The first circuit and the second circuit are installed in a chip.

The semiconductor integrated circuit can operate without changing a power supply voltage at a low temperature by operating a low VT logic circuit configured by transistors whose threshold voltage is low at a low temperature based on a temperature of a main circuit, and operation temperature range can be expanded easily. Further, leak current at a high temperature can be reduced by operating a high VT logic circuit configured by transistors whose threshold voltage is high at a high temperature.

According to the present invention, we can provide a semiconductor integrated circuit which provides wide operating temperature range and reduces a leak current.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a view showing a semiconductor integrated circuit of a first exemplary embodiment of the present invention;

FIG. 2 is a view showing a relation between junction temperature and leak electrical power of a transistor which is used for the semiconductor integrated circuit of the first exemplary embodiment of the present invention;

FIG. 3 is a view showing a semiconductor integrated circuit of a second exemplary embodiment of the present invention;

FIG. 4 is a view describing a technique of Sakiyama et al.;

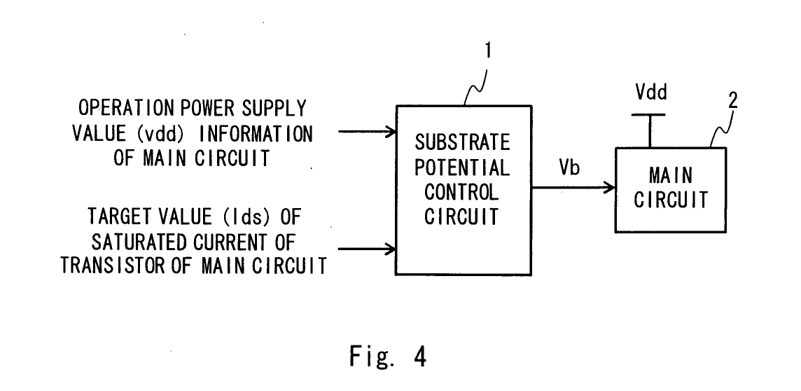

FIG. 5 is a view describing a technique of Ono et al.; and

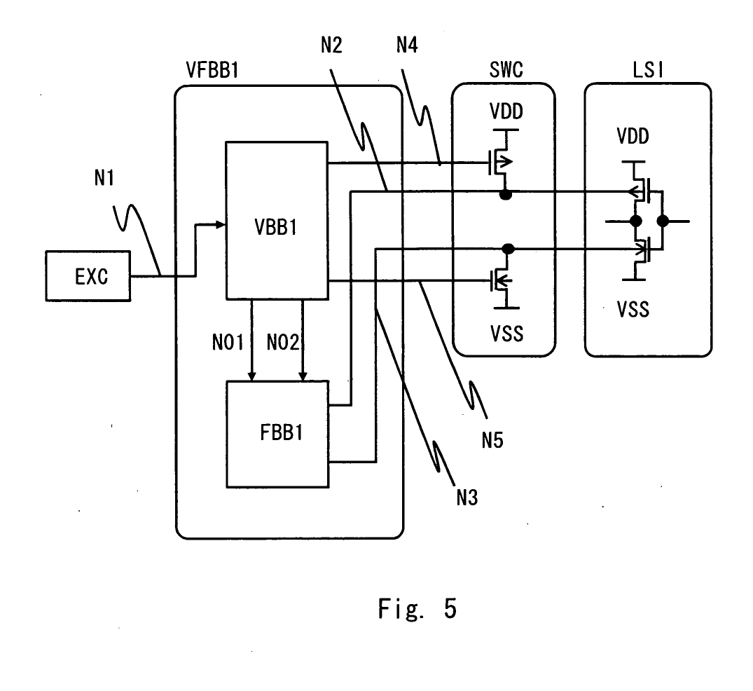

FIG. 6 is a view describing a technique of Sato et al.

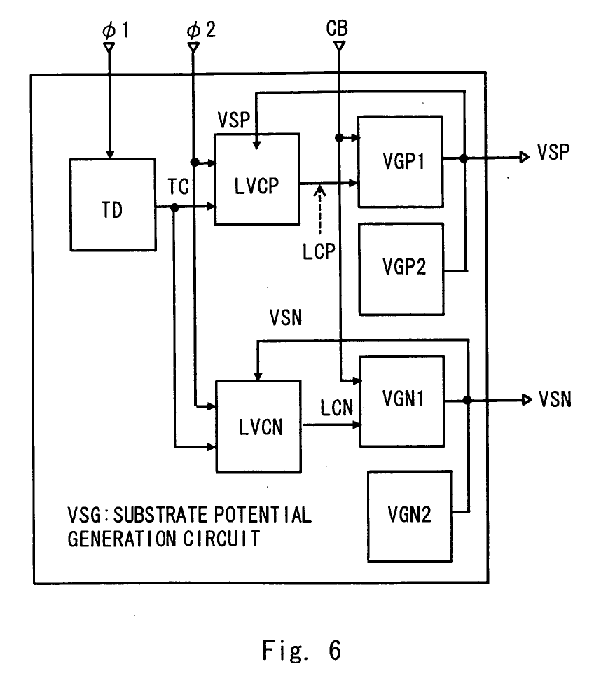

### DETAILED DESCRIPTION OF THE EXEMPLARY EMBODIMENTS

### First Exemplary Embodiment

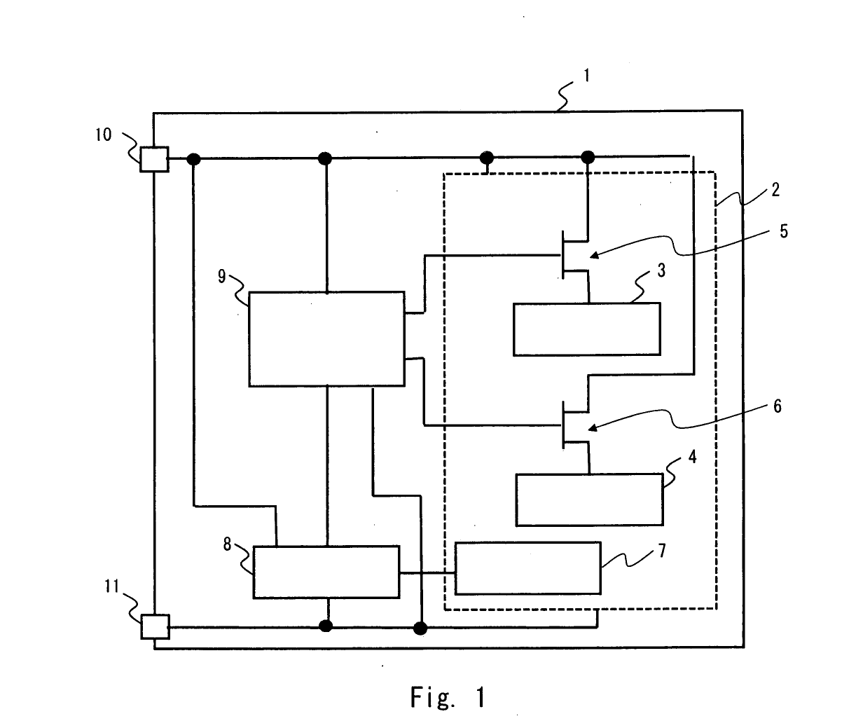

A semiconductor integrated circuit of a first exemplary embodiment will be described in reference to FIG. 1. FIG. 1 is a view showing a semiconductor integrated circuit of a first exemplary embodiment of the present invention. As shown in FIG. 1, a semiconductor integrated circuit 1 includes a main circuit 2, a high VT logic circuit 3, a low VT logic circuit 4, a high VT logic power supply switch 5, a low VT logic power supply switch 6, a temperature detect circuit 7, a temperature determination circuit 8, a control circuit 9, a power supply terminal 10 and a GND terminal 11. Power supply voltage from the power supply terminal 10 and GND voltage from the GND terminal 11 are supplied to the main circuit 2, the temperature determination circuit 8 and the control circuit 9.

The main circuit 2 includes a circuit which realizes main function of the semiconductor integrated circuit 1. The main circuit 2 includes the high VT logic circuit 3 and the low VT logic circuit 4 as main function part. The high VT logic circuit 3 is configured in the same way as the low VT logic circuit 4. That is, the high VT logic circuit 3 and the low VT logic circuit 4 realize the same logic. Therefore, the semiconductor integrated circuit 1 includes at least two same logic circuits.

The high VT logic circuit 3 is configured by a MOS transistor and the threshold voltage is a first threshold voltage. The low VT logic circuit 4 is configured by a MOS transistor and the threshold voltage is a second threshold voltage. The first threshold voltage is higher than the second threshold voltage. Therefore the low VT logic circuit 4 is configured by a MOS transistor whose threshold voltage is lower than a threshold voltage of a MOS transistor that configures the high VT logic circuit 3 is configured.

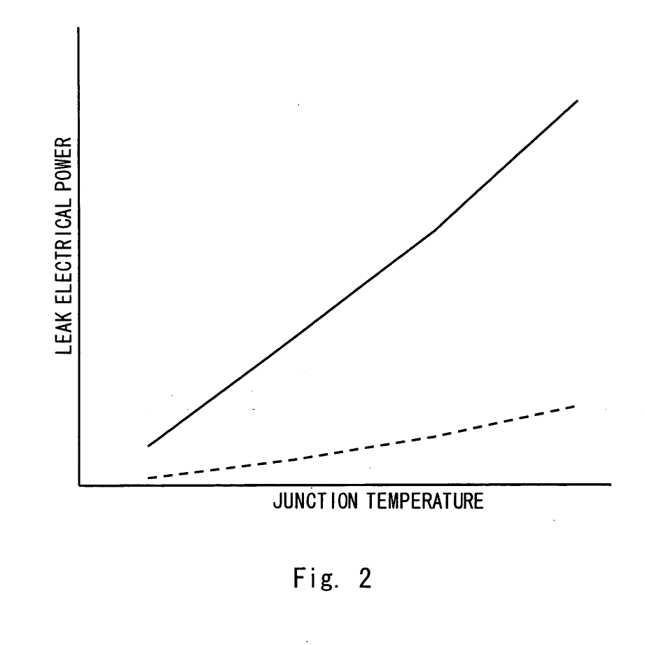

FIG. 2 is a view showing a relation between junction temperature and leak electrical power of a transistor which is used for the semiconductor integrated circuit of the first exemplary embodiment of the present invention. In FIG. 2, a horizontal axis shows junction temperature (temperature of a connection portion of the main circuit 2 in the semiconductor integrated circuit 1), and a vertical axis shows a leak electrical power. A solid line shows a transistor whose threshold voltage is low, and a dashed line shows a transistor whose threshold voltage is high. Note that, in this example, junction temperature is shown as an example of the temperature of a chip where the high VT logic circuit 3 and the low VT logic circuit 4 are installed. However an example of the temperature of chip is not limited to this.

As shown in FIG. 2, when junction temperature is increased, both of leak electric powers of transistors whose threshold voltage is high and whose threshold voltage is low are increased. However, leak electrical power of the transistor whose threshold voltage is low is increased more than that of the transistor whose threshold voltage is high.

According to the present exemplary embodiment, a transistor whose threshold voltage is higher than that of the low VT logic circuit 4 and whose leak current is low at a high temperature is used as the high VT logic circuit 3.

A transistor whose threshold voltage is lower than that of the high VT logic circuit 3 and whose leak current is high at a high temperature is used as the low VT logic circuit 4. By using the low VT logic circuit 4, the transistor can be operated without having a power supply voltage even at low temperature. Hence, by using the high VT logic circuit 3 and the low VT logic circuit 4 which are configured by transistors which have different threshold voltages, temperature range where the transistor can operate can be expanded.

The high VT logic circuit 3 is connected to one end of the high VT logic power supply switch 5. The other end of the high VT logic power supply switch 5 is connected to the power supply terminal 10. ON/OFF of the high VT logic power supply switch 5 is controlled by the control circuit 9. The power supply voltage from the power supply terminal 10 is supplied to the high VT logic circuit 3 by turning on the high VT logic power supply switch 5.

The low VT logic circuit 4 is connected to one end of the low VT logic power supply switch 6. The other end of the low VT logic power supply switch 6 is connected to the power supply terminal 10. ON/OFF of the low VT logic power supply switch 6 is controlled by the control circuit 9. The power supply voltage from the power supply terminal 10 is supplied to the low VT logic circuit 4 by turning on the low VT logic power supply switch 6.

The main circuit 2 includes the temperature detect circuit 7. The temperature detect circuit 7 detects a temperature of a chip where the high VT logic circuit 3 and the low VT logic circuit 4 are installed. Here, the temperature detect circuit 7 detects above-mentioned junction temperature. The temperature detect circuit 7 is connected to the temperature determination circuit 8. Temperature information detected by the temperature detect circuit 7 is input to the temperature determination circuit 8. The temperature determination circuit 8 determines whether the detected result is high temperature condition or low temperature condition based in the temperature information, and the determination result is input to the control circuit 9.

The control circuit 9 makes the high VT logic circuit 3 or the low VT logic circuit 4 operate depending on the temperature of the chip where the high VT logic circuit 3 and the low VT logic circuit 4 are installed. Specifically, the control circuit 9 turns on the high VT logic power supply switch 5 or the low VT logic power supply switch 6 depending on the determination result of the temperature determination circuit 8. If the temperature determination circuit 8 determines that the chip is in the high temperature condition, the control circuit 9 turns on the high VT logic power supply switch 5 and turns off the low VT logic power supply switch 6. By this, the control circuit 9 the high VT logic circuit 3 operate in the high temperature condition.

When a temperature of the main circuit 2 of the semiconductor integrated circuit 1 is decreased, and the temperature determination circuit 8 determines that the chip is in the low temperature condition, the control circuit 9 turns on the low VT logic power supply switch 6 and turns off the high VT logic power supply switch 5. By this, the control circuit 9 makes the low VT logic circuit 4 operate in the low temperature condition.

According to the semiconductor integrated circuit 1 of the present exemplary embodiment, the main circuit 2 has main function. Then the main circuit 2 includes the high VT logic circuit 3 and the low VT logic circuit 4. The high VT logic circuit 3 is configured by high VT transistors which become low leak at high temperature. The low VT logic circuit 4 is configured by low VT transistors which become high leak at the high temperature; but become low leak at the low temperature so as to make it easy to expand an operation voltage range.

Here, an operation of the semiconductor integrated circuit 1 will be described. Firstly, the temperature of the main circuit 2 is detected by the temperature detect circuit 7. The temperature determination circuit 8 determines whether the chip where the high VT logic circuit 3 and the low VT logic circuit 4 are installed is in a high temperature condition or a low temperature condition based on the temperature information detected by the temperature detect circuit 7.

In the case where the temperature determination circuit 8 determines the chip is in the high temperature condition, the temperature determination circuit 8 outputs a determination signal showing the high temperature condition to the control circuit 9. The control circuit 9 turns on the high VT logic power supply switch 5 and makes the high VT logic circuit 3 be operating state by supplying a power supply voltage to the high VT logic circuit 3. The control circuit 9 turns off the low VT logic power supply switch 6 and makes the low VT logic circuit 4 be non-operating state. This can reduce the leak current during the high temperature operation.

On the other hand, if the temperature of the main circuit 2 of the semiconductor integrated circuit 1 is decreased and the detecting temperature of the temperature detect circuit 7 is lower than a predetermined temperature, the temperature determination circuit 8 determines the chip is in a low temperature condition. Then the temperature determination circuit 8 outputs the determination signal showing a low temperature condition to the control circuit 9. In this case, the control circuit 9 turns on the low VT logic power supply switch 6 and makes the low VT logic circuit 4 be operating state by supplying the power supply voltage. The control circuit 9 turns off the high VT logic power supply switch 5 and makes the high VT logic circuit 3 be non-operating state.

A low VT transistor has originally low threshold voltage. Thus, even if the threshold voltage is increased at low temperature condition, there is no need to increase the power supply voltage as high as high VT transistor. This can make the semiconductor integrated circuit 1 operate without changing the power supply voltage at the low temperature condition.

As explained above, the semiconductor integrated circuit 1 can operate without changing the power supply voltage at a low temperature condition by detecting temperature of the semiconductor chip, and by operating the low VT logic circuit 4 which is configured by transistors whose threshold voltage is low at a low temperature. This can readily expand the operation temperature range of the semiconductor integrated circuit 1. Further, at the high temperature, leak current can be reduced by operating the high VT logic circuit 3 which is configured by transistors whose threshold voltage is high.

### Second Exemplary Embodiment

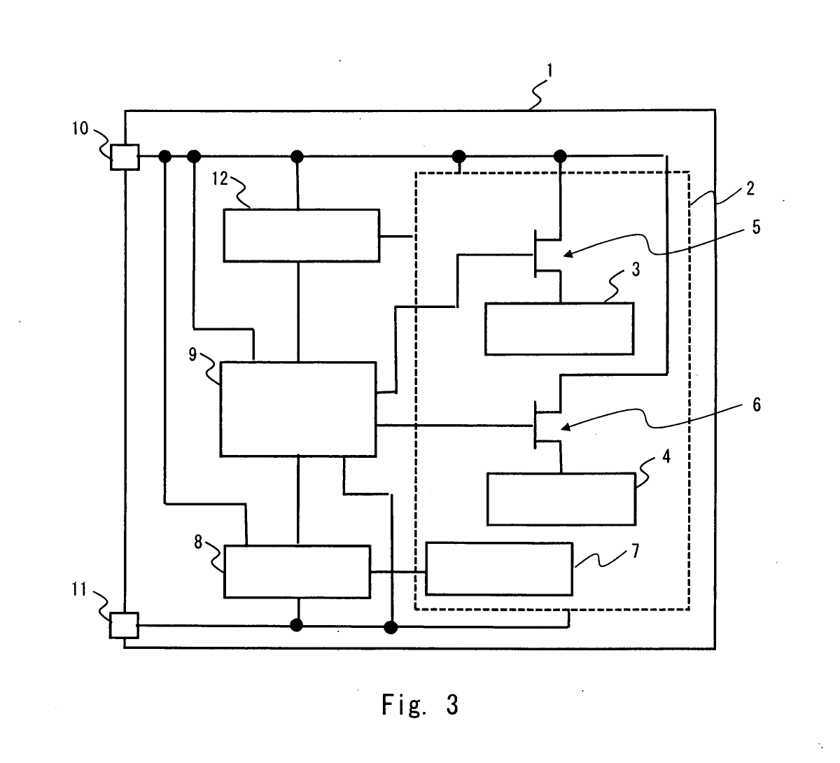

A semiconductor integrated circuit of a second exemplary embodiment will be described in reference to FIG. 3. FIG. 3 is a view showing a semiconductor integrated circuit of a second exemplary embodiment of the present invention. In the present exemplary embodiment, the same elements as the first exemplary embodiment are denoted by the same reference numbers and their explanations are omitted as appropriate. The present exemplary embodiment is an example which also uses a substrate bias technique which is used widely as a conventional technique.

As shown in FIG. 3, the semiconductor integrated circuit 1 of the present exemplary embodiment includes, as similarly as the first exemplary embodiment, the main circuit 2, the high VT logic circuit 3, the low VT logic circuit 4, the high VT logic power supply switch 5, the low VT logic power supply switch 6, the temperature detect circuit 7, the temperature determination circuit 8, the control circuit 9, the power supply terminal 10 and the GND terminal 11.

The functions of the high VT logic circuit 3, the low VT logic circuit 4, the high VT logic power supply switch 5, the low VT logic power supply switch 6 and the temperature detect circuit 7 provided in the main circuit 2 of the semiconductor integrated circuit 1 are same as the explanation of the first exemplary embodiment, so detailed explanation will be omitted.

The semiconductor integrated circuit 1 of the present exemplary embodiment includes a substrate bias power supply 12 in addition to the configuration of FIG. 1. The substrate bias power supply 12 is connected to the power supplies terminal 10 and the control circuit 9. The substrate bias power supply 12 apply substrate voltage to the main circuit 2 in order to increase a threshold voltage of transistors in response to a control signal from the control circuit 9.

Here, the operation of the semiconductor integrated circuit 1 of the present exemplary embodiment will be explained. First, the temperature detect circuit 7 installed in the main circuit 2 of the semiconductor integrated circuit 1 detects a temperature of the chip where the high VT logic circuit 3 and the low VT logic circuit 4 are installed. The temperature determination circuit 8 determines whether the main circuit 2 is in a high temperature condition or a low temperature condition based on the temperature information detected by the temperature detect circuit 7.

In the case where the temperature determination circuit 8 determines the chip is in the high temperature condition, the temperature determination circuit 8 outputs a determination signal showing the high temperature condition to the control circuit 9. The control circuit 9 turns on the high VT logic power supply switch 5 and makes the high VT logic circuit 3 be operating state by supplying a power supply voltage to the high VT logic circuit 3. The control circuit 9 turns off the low VT logic power supply switch 6 and makes the low VT logic circuit 4 be non-operating state.

Further, the control circuit 9 turns on the substrate bias power supply 12, and the substrate bias power supply 12 applies substrate bias voltage to the high VT logic circuit 3 of the main circuit 2. That is, the substrate bias power supply 12 applies the substrate voltage to the main circuit 2 based on the temperature detected by the temperature detect circuit 7. This can increase the threshold voltage of a transistor which configures the high VT logic circuit 3, and can reduce leak current.

On the other hand, if the temperature of the main circuit 2 of the semiconductor integrated circuit 1 is decreased and the detecting temperature of the temperature detect circuit 7 is below a predetermined temperature, the temperature determination circuit 8 determines the chip is in a low temperature condition. Then the temperature determination circuit 8 outputs the determination signal showing a low temperature condition to the control circuit 9.

In this case, the control circuit 9 turns on the low VT logic power supply switch 6 and makes the low VT logic circuit 4 be operating state by supplying the power supply voltage. The control circuit 9 turns off the high VT logic power supply switch 5 and makes the high VT logic circuit 3 be non-operating state. Further, the control circuit 9 turns off the substrate bias power supply 12 and the substrate bias power supply, 12 does not apply the substrate voltage to the main circuit 2.

As explained above, according to the present invention, two circuit blocks which have same function are installed in the semiconductor integrated circuit. One of them is high VT logic circuit configured by the high VT transistors whose threshold voltage is high, and the other of them is low VT logic circuit configured by the low VT transistors whose threshold voltage is low.

Further, the temperature detect circuit 7 detects the temperature of the semiconductor integrated circuit, the high VT logic circuit configured by transistors whose threshold voltage is high operates in the high temperature condition based on the temperature information, and the low VT logic circuit configured by the transistors whose threshold voltage are low operates in the low temperature based on the temperature information.

This can eliminate changing of power supply voltage at the low temperature operation. As a result, the semiconductor integrated circuit can operate with a constant power supply voltage condition, and an operation temperature range can be expanded without depending on the power supply voltage. Further, when the semiconductor chip is in a high temperature condition, the high VT logic circuit configured by the high VT transistors can operate, which can reduce a leak current.

It is apparent that the present invention is not limited to the above embodiment but may be modified and changed without departing from the scope and spirit of the invention. In the above-mentioned exemplary embodiment, the semiconductor integrated circuit 1 has two same logic circuits (the high VT logic circuit 3 and low VT logic circuit 4). However the semiconductor integrated circuit 1 may have more than two same logic circuits. These same logic circuits can be configured by MOS transistors whose thresholds are different.

The first and second exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor integrated circuit comprising:
a first circuit which is configured by a first MOS transistor, a threshold voltage of the first MOS transistor being a first threshold voltage;
a second circuit which has same logic as the first circuit, and is configured by a second MOS transistor, a threshold voltage of the second MOS transistor being a second threshold voltage, the second threshold voltage being lower than the first threshold voltage; and
a control circuit which makes one of the first circuit and the second circuit operate depending on a temperature of a chip, the first circuit and the second circuit being installed in a chip.

2. The semiconductor integrated circuit according to claim 1, further comprising:
a temperature detecting circuit which detects a temperature of the chip; and
a temperature determination circuit which determines whether or not the temperature of the chip detected by the temperature detection circuit is equal to or higher than a predetermined temperature,
wherein when the temperature determination circuit determines the temperature of the chip is equal to or higher than the predetermined temperature, the control circuit makes the first circuit operate, and
when the temperature determination circuit determines the temperature of the chip is lower than the predetermined temperature, the control circuit makes the second circuit operate.

3. The semiconductor integrated circuit according to claim 1, further comprising a substrate bias power supply which applies a substrate voltage based on the temperature of the chip detected by the temperature detection circuit.

4. The semiconductor integrated circuit according to claim 2, further comprising a substrate bias power supply which applies the substrate voltage when the temperature determination circuit determines the temperature of the chip is equal to or higher than the predetermined temperature.
